(19) United States
(12) Patent Application Publication
(10) Pub. No.: US 2010/0008042 A1
(43) Pub. Date: Jan. 14, 2010

(54) HEAT DISSIPATION DEVICE

(75) Inventor: HONG-BO XU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) Co.,LTD., Shenzhen City (CN); HON HAI PRECISION INDUSTRY CO., LTD, Tu-Cheng (TW)

(21) Appl. No.: 12/169,641

(22) Filed: Jul. 9, 2008

(51) Int. Cl. H05K 7/20

(52) U.S. Cl. 361/697

(57) ABSTRACT

A heat dissipation device includes a first heat sink and a second heat sink, a bridge sandwiched between the first and second heat sinks, a plurality of fasteners extending onto the first and second heat sinks and the bridge to combine the two heat sinks and the bridge, a clip mounted on the bridge and positioned between the two heat sinks, and a fan located on the first and second heat sinks. Each of the heat sinks includes a base and a plurality of fins extending from the base. A plurality of grooves is defined in the bridge and the base of each of the heat sinks to accommodate the fasteners.

### BACKGROUND OF THE INVENTION

1. Field of the Invention

The present invention relates to a heat dissipation device used in association with electronic components.

2. Description of Related Art

Computer electronic components, such as central processing units (CPUs), generate large amounts of heat during normal operation. If the heat is not properly dissipated, it can adversely affect operational stability of the electronic components and damage associated electronic devices. A heat dissipation device is often attached to a top surface of a CPU to dissipate heat therefrom.

Conventionally, a heat dissipation device includes a heat sink, a clip locked on the heat sink, and a fan located on the heat sink. The heat sink has a center portion recessed by milling to provide a space to receive the clip. Material is wasted by the milling procedure, which increases the manufacturing cost.

What is needed, therefore, is an improved heat dissipation device which can overcome the described limitation.

### SUMMARY OF THE INVENTION

A heat dissipation device includes a first heat sink and a second heat sink, a bridge sandwiched therebetween, a plurality of fasteners extending onto the first and second heat sinks and the bridge to combine the two heat sinks and the bridge, a clip mounted on the bridge and positioned between the two heat sinks, and a fan located on the first and second heat sinks. Each of the heat sinks includes a base and a plurality of fins extending from the base. A plurality of grooves is defined in the bridge and the base of each of the heat sinks for the fasteners to extend thereinto.

Other advantages and novel features of the present invention will become more apparent from the following detailed description when taken in conjunction with the accompanying drawings.

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an assembled, isometric view of a heat dissipation device in accordance with a first embodiment of the present invention.

FIG. 2 is an exploded, isometric view of the heat dissipation device in FIG. 1.

FIG. 3 is an assembled, isometric view of a heat dissipation device in accordance with a second embodiment of the present invention.

### DETAILED DESCRIPTION OF THE INVENTION

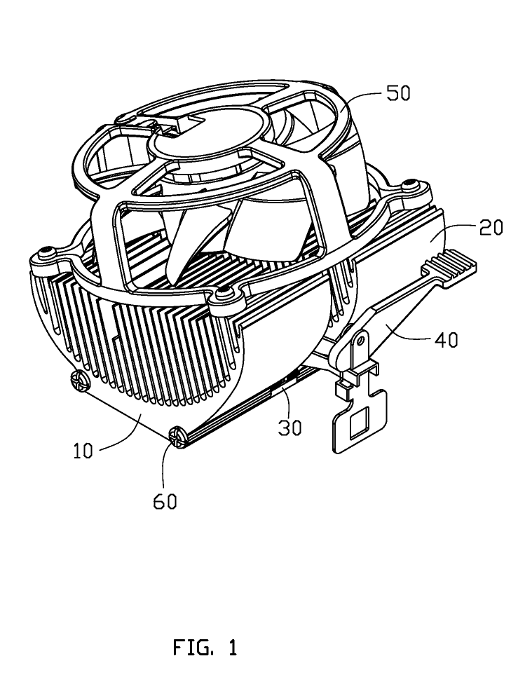

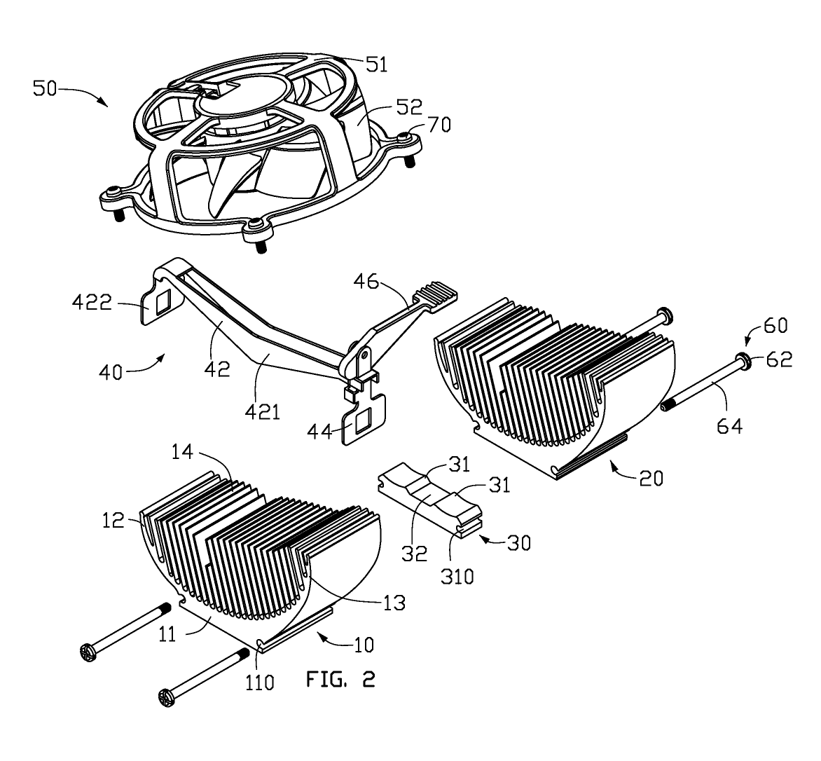

Referring to FIGS. 1-2, a heat dissipation device in accordance with a preferred embodiment of the invention comprises a first heat sink 10, a second heat sink 20 located beside and spaced from the first heat sink 10, a bridge 30 sandwiched between the two heat sinks 10, 20, a clip 40 mounted on the bridge 30 and positioned between the two heat sinks 10, 20 and a fan 50 located on the two heat sinks 10, 20. Four fasteners 60 extend onto the two heat sinks 10, 20 and the bridge 30, combining the same.

In the present embodiment, the first heat sink 10 is identical to the second heat sink 20, each comprising a substantially rectangular base 11 and a plurality of fins 14 extending perpendicularly therefrom. Two grooves 110 are defined in two ends of the base 11. The grooves 110 transversely extend through the base 11. Two conducting arms 12, 13 extend upwardly and protrude outwardly from the two ends of the base 11. The two conducting arms 12, 13 are curved. The two conducting arms 12, 13 and the base 11 cooperatively present a substantially C-shaped configuration. The conducting arm 13 extends upwardly beyond the conducting arm 12, such that a top end of the conducting arm 13 is above that of the conducting arm 12. The fins 14 are parallel and extend upwardly from the base 11 and inner surfaces of the two conducting arms 12, 13. Top ends of the fins 14 define a plane angular to the base 11. The first and second heat sinks 10, 20 are formed by aluminum extrusion.

The bridge 30 is of a highly heat-conductive material such as copper or other material. The bridge 30 is substantially a rectangular block. A length of the bridge 30 is the same as that of the base 11 of each of the first and second heat sinks 10, 20. A bottom surface of the bridge 30 contacts a heat generating component (not shown), such as a CPU, for absorbing heat generated thereby. Corresponding to and in alignment with the grooves 110 in the two ends of the base 11 of each of the first and second heat sinks 10, 20, two grooves 310 are defined in two ends of the bridge 30. Two protrusions 31 extend from a top surface of the bridge 30. The two protrusions 31 are spaced apart. A flat portion 32 is defined between the two protrusions 31 and below two portions located at outer sides thereof.

Four fasteners 60, such as, for example, screws, extend into the grooves 110 of the first and second heat sinks 10, 20 and are threaded in the grooves 310 of the bridge 30 to combine the bridge 30 and the first and second heat sinks 10, 20. Each of the fasteners 60 comprises a cap 62 and a bolt 64 with threads (not labeled) formed at an end of the bolt 64 extending from the cap 62. Each of the fasteners 60 extends into a corresponding groove 110 of the base 11 with the end of the bolt 64 threaded in the groove 310 of the bridge 30. In the present embodiment, the fasteners 60 tap threads by self-tapping in the grooves 310 of the bridge 30 when the fasteners 60 are engaged in the grooves 310 of the bridge 30. Understandably, threads can be formed in the grooves 110 of the first and second heat sinks 10, 20 and the grooves 310 of the bridge 30 before the assembly thereof in alternative embodiments.

The clip 40 comprises an elongated arm 42, a locking member 44, and a handle 46. The handle 46 is pivotally connected to the locking member 44 after the locking member 44 is inserted through the elongated arm 42. The elongated arm 42 comprises a pair of substantially V-shaped braces 421 and a latching leg 422 extending downwardly from an end of the braces 421 away from the locking member 44 and the handle 46. The two braces 421 are separate but connected each other at two opposite ends thereof. A bottom end of each of the braces 421 positions on the flat portion 32 of the bridge 30, and two lateral sides of each of the braces 421 abut the two protrusions 31 of the bridge 30 to prevent motion of the clip 40 relative to the bridge 30.

The fan 50 comprises a fan holder 51 and an impeller 52 received therein. A plurality of holes (not labeled) is defined in the fan holder 51 for receiving screws 70 to secure the fan 50 on the first and second heat sinks 10, 20.

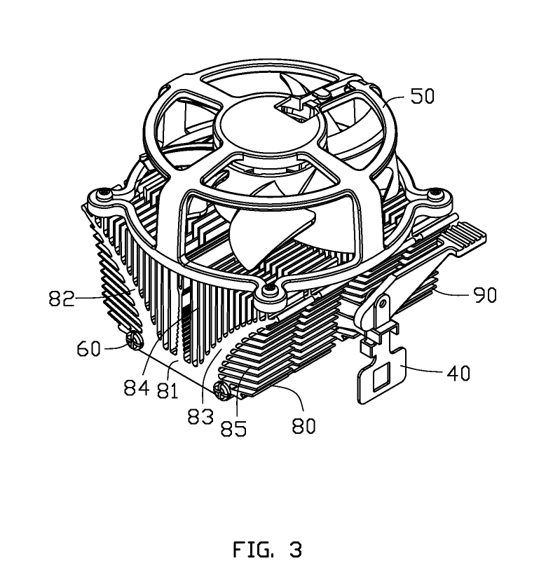

Referring to FIG. 3, a heat dissipation device in accordance with a second embodiment of the present invention is shown. The heat dissipation device of the present embodiment is identical to the heat dissipation device in accordance with the first embodiment of the present invention, differing only in the configuration of the first and second heat sinks 80, 90. Each of the first and second heat sinks 80, 90 comprises a base 81. Two conducting arms 82, 83 extend upwardly and protrude outwardly from two ends of the base 81. The two conducting arms 82, 83 are symmetrical relative to a center line of the base 81. A plurality of first fins 84 extends perpendicularly from the base 81 and inner surfaces of the two conducting arms 82, 83. Top ends of the first fins 84 and top ends of the conducting arms 82, 83 define a plane substantially parallel to the base 81 for mounting of the fan 50 thereon. A plurality of second fins 85 extends horizontally and outwardly from outer surfaces of the two conducting arms 82, 83. Length of the second fins 85 decreases gradually from bottom to top of the conducting arms 82, 83.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device, comprising:
a first heat sink and a second heat sink, the two heat sinks each comprising a base and a plurality of fins extending from the base;
a bridge sandwiched between the bases of the first and second heat sinks;
at least one fastener extending onto the bases of the first and second heat sinks and the bridge to combine the two heat sinks and the bridge; and
a clip mounted on the bridge and positioned between the two heat sinks.

2. The heat dissipation device as claimed in claim 1, wherein two conducting arms extend from two ends of each of the bases of the heat sinks.

3. The heat dissipation device as claimed in claim 2, wherein the two conducting arms extend upwardly and protrude outwardly, and the two conducting arms and a corresponding base cooperatively present a C shape.

4. The heat dissipation device as claimed in claim 3, wherein the plurality of fins are parallel and extend perpendicularly from the two conducting arms and the corresponding base.

5. The heat dissipation device as claimed in claim 4, wherein one of the two conducting arms extends longer than the other, and wherein top ends of the fins define a plane angular to the corresponding base.

6. The heat dissipation device as claimed in claim 2, wherein the two conducting arms extend upwardly and protrude outwardly, and wherein the fins include first fins extending perpendicularly from the corresponding base and inner surfaces of the two conducting arms and second fins extending horizontally and outwardly from outer surfaces of the two conducting arms.

7. The heat dissipation device as claimed in claim 1, wherein two protrusions extend upwardly from a top surface of the bridge.

8. The heat dissipation device as claimed in claim 7, wherein the clip comprises a V-shaped brace pressing on the two protrusions of the bridge.

9. The heat dissipation device as claimed in claim 1, wherein two grooves are defined in two opposite ends of the bridge and the base of each of the first and second heat sinks, and wherein two first fasteners extend through the grooves of the first heat sink to be threaded in the grooves of the bridge, and two second fasteners extend through the grooves of the second heat sink to be threaded in the grooves of the bridge.

10. The heat dissipation device as claimed in claim 1, further comprising a fan located on the first and second heat sinks.

11. A heat dissipation device, comprising:
a first heat sink and a second heat sink, the two heat sinks each comprising a base and a plurality of fins extending from the base;
a bridge sandwiched between the bases of the first and second heat sinks;
a plurality of fasteners extending onto the bases of the first and second heat sinks and the bridge to combine the two heat sinks and the bridge;
a clip mounted on the bridge and positioned between the two heat sinks; and
a fan located on the fins of the first and second heat sinks.

12. The heat dissipation device as claimed in claim 1, wherein two conducting arms extend from two ends of each of the bases of the heat sinks.

13. The heat dissipation device as claimed in claim 12, wherein the two conducting arms extend upwardly and protrude outwardly, and one of the two conducting arms extends beyond the other.

14. The heat dissipation device as claimed in claim 13, wherein the plurality of fins are parallel and extend perpendicularly from the two conducting arms and the corresponding base, and wherein top ends of the fins define a plane angular to the base on which the fan is mounted.

15. The heat dissipation device as claimed in claim 12, wherein the two conducting arms extend upwardly and protrude outwardly, and wherein the fins include first fins extending perpendicularly from a corresponding base and inner surfaces of the two conducting arms and second fins extending horizontally and outwardly from outer surfaces of the two conducting arms.

16. The heat dissipation device as claimed in claim 11, wherein two grooves are defined in two ends of the bridge and the base of each of the first and second heat sinks, and wherein the fasteners include four screws extending into the grooves to combine the bridge and the first and second heat sinks together.
